(19) United States
(12) Patent Application Publication
(10) Pub. No.: US 2004/0261711 A1
(43) Pub. Date: Dec. 30, 2004

(54) Apparatus and system for, and method of supplying process gas in semiconductor device manufacturing equipment

(76) Inventors: Sung-Sok Choi, Suwon-si (KR); Jin-Jun Park, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 10/813,439

(22) Filed: Mar. 31, 2004

(30) Foreign Application Priority Data
Mar. 31, 2003 (KR) 2003-19877

(51) Int. Cl. C23C 16/00

(52) U.S. Cl. 118/723 E

(57) ABSTRACT

An apparatus for supplying a process gas onto a wafer includes a plurality of nozzles integrated with an electrode plate of an upper electrode. The nozzles are configured so that the flow rate of the process gas towards the wafer is greater at locations across from the outer peripheral portion of the wafer than from a location across from the center of the wafer. The plurality of nozzles thus can distribute the gas so that the density of the gas is uniform across the entire upper entire upper surface of the wafer.

### BACKGROUND OF THE INVENTION

1. Field of the Invention

The present invention relates to the manufacturing of semiconductor devices. More particularly, the present invention relates to the supplying of process gas that is to be converted into plasma in semiconductor device manufacturing equipment.

2. Description of the Related Art

Processes such as etching or metal deposition processes in the manufacturing of a semiconductor device convert a supplied process gas into a plasma using radio frequency power to make the process gas reactive to a surface of a wafer.

Referring to FIG. 1, semiconductor device manufacturing equipment 10 that produces plasma using radio frequency power generally includes a chamber 12 in which a vacuum pressure atmosphere can be created, a lower electrode 14 that supports a wafer W and is disposed at a lower part of the chamber 12, and an upper electrode 16 disposed at an upper part of the chamber 12 opposite the lower electrode 14. Herewith, a process gas is supplied onto the entire upper surface of the wafer W, and radio frequency power is applied to the upper electrode 16 and the lower electrode 14. A vacuum is formed in the chamber 12 by vacuum pressure provided through an exhaust line 18 that is connected to the chamber 12.

Referring to FIG. 2, the process gas is supplied into the chamber interior 12 via the upper electrode 16. To this end, the upper electrode 16 includes an electrode plate 20, and a plurality of nozzles 22a, 22b from which the process gas issues towards the upper surface of the wafer W. The nozzles 22a, 22b are assembled to the electrode plate 20 so as to be integral therewith.

Of the nozzles 22a, 22b, the nozzle 22a that is located at the center of the electrode plate 20 vertically opposite the center of the wafer W will be referred to as the central nozzle, and the nozzles 22b which are disposed at equal intervals from and around the central nozzle 22a will be referred to as edge nozzles. The edge nozzles 22b are also the ones disposed vertically opposite a portion of the wafer W just inside the peripheral edge of the wafer.

As shown in FIG. 3, the central nozzle 22a and the edge nozzles 22b have the same shape. Each of the nozzles 22a, 22b is provided with five gas holes (h) for dividing process gas supplied to the upper electrode 16 through a supply line 26 into jets of gas having equal pressure, and for directing the jets of the process gas towards the wafer W.

That is, the process gas passing through the electrode plate 20 is divided into equal amounts by the nozzles 22a, 22b. Then, as shown in FIG. 4, the process gas gradually over time spreads radially outwardly within respective ranges T from each of the central 22a and edge 22b nozzles. However, the actual distribution of the process gas has a Gaussian distribution as shown in FIG. 5 at the upper surface of the wafer W due to the congested vacuum pressure atmosphere in the chamber interior. More specifically, the process gas is concentrated at a central region of the wafer W due to the overlapping regions of the gas issuing from the nozzles 22a, 22b. The density of the process gas concentrated at the central region of the wafer can be represented by (L+(4×l)).

FIG. 6 shows a simulation of an etching process in which the process gas distributed in the manner above is excited using radio frequency power. The results shown in FIG. 6 indicate that the process reaction that takes place at the center portion of the wafer W is excessive and that the process reaction that takes place at the peripheral portion of the wafer is insufficient. As shown in FIG. 7a, a film of material is left on the peripheral edge portion of the wafer W where the insufficient reaction of the etching process takes place. This un-removed material must be subsequently be removed by an additional process, e.g., a cleaning procedure or other etching process.

These results are due, in part, to the fact that the respective nozzles 22a, 22b each distribute equal amounts of the process gas into the chamber 12, and that the interval D (FIG. 2) between adjacent ones of the edge nozzles 22b is larger than the interval D′ between any one edge nozzle 22b and the central nozzle 22a.

Accordingly, the radio frequency power applied through the upper and lower electrodes 16, 14 creates a stronger reaction at the center of the wafer W. An edge ring 24 has been provided at an outer circumference of the wafer W, as shown in FIG. 1, in an attempt to solve this problem by extending the influence of the radio frequency power to the outer peripheral edge region of the wafer W. However, practice shows that the effect provided by the edge ring 24 is insufficient.

In the meantime, another problem concerning the distribution of the process gas is that a potential difference occurs between process gas layers at a central region of the wafer W and the outer peripheral edge region of the wafer W when the radio frequency power is applied to the process gas through the upper and lower electrodes 16, 14. This potential difference brings about a discharge that damages the electrode plate 20 or the surface of the wafer W. The damage manifests itself as a hemi-spherical type of defect on the electrode plate 20, as shown in the photograph of FIG. 7b. The material of the defect eventually falls onto the upper surface of the wafer W and thus, in turn, damages the upper surface of the wafer during the etching process, as shown in the photograph of FIG. 7c.

FIG. 8 is a graph of the results of ten tests wherein the level of the radio frequency power is gradually increased over each of the tests for a particular type of process gas distributed by the upper electrode 16 of the prior art, and the frequency of the defects are noted. FIG. 9 is a graph of results of eight tests wherein the vacuum pressure within the chamber 12 is increased over each of the tests for a particular type of process gas distributed by the upper electrode 16 of the prior art, and the frequency of the defects are noted.

As these results show, the higher the level of the radio frequency power and the level of the vacuum pressure becomes, in other words, the higher the rate of the reaction becomes, the greater the frequency of the defects becomes. Thus, low levels of radio frequency power and vacuum pressure should be provided to suppress the generation of defects otherwise caused by discharge within the process chamber 12. However, lowering the levels of radio frequency power and vacuum pressure increase the processing time and hence, reduce productivity.

FIG. 10 shows data of the frequency of defects on the electrode plate 20 generated according to four tests in which the flow rates of respective ones of the gases making up the process gas are varied. FIG. 10 can thus be used to decide the level of the radio frequency power and the vacuum pressure appropriate for formulating the process gas to keep the number of defects low. The process gas is continuously supplied while the flow rates of the individual gases change for each unit process change throughout the course of the overall process. However, a great amount of time is required to adjust the process conditions in this way.

That is, in order to continuously supply the process gas while changing the formulation, and at the same time ensure a low number of defects due to discharge in the process chamber, the radio frequency power and vacuum pressure must could be kept at low levels or process conditions, such as flow rate, could be adjusted. However, these solutions are difficult to implement and/or result in long processing times.

### SUMMARY OF THE INVENTION

Accordingly, an object of the present invention is to provide a method of and means for supplying process gas onto a wafer such that the density of the gas is uniform across the entire upper surface of the wafer.

Another object of the present invention is to provide a method of and apparatus for supplying a process gas in a semiconductor device manufacturing process using radio frequency power, wherein the process can be carried out in a relatively short amount time.

Still another object of the present invention is to provide a method of and apparatus for supplying a process gas in a semiconductor device manufacturing process, that facilitate a rapid changing of the process conditions.

According to one aspect of the present invention, the present invention provides an apparatus for supplying a process gas onto a wafer comprising a plurality of nozzles configured so that a flow rate of the process gas increases in a radially outward direction from a location vertically opposite the center of the wafer. These nozzles include a central nozzle to be disposed vertically opposite the center wafer, and one or more groups of edge nozzles.

The plurality of nozzles may have the same shape with the spacing therebetween decreasing in the radially outward direction from the location vertically opposite the center of the wafer. Alternatively, the plurality of nozzles are configured so that the flow rate of the process gas through the nozzles is higher the further out one proceeds from the location vertically opposite to the center of the wafer.

According to another aspect of the present invention, one portion of the supplied process gas is injected at a flow rate of 0˜15 weight percent per unit time, of the total amount of the process gas being supplied, onto the central portion of the upper surface of the wafer from the central nozzle, i.e., from a location directly above the center of the wafer. At the same time, the remainder of the supplied process gas is injected onto a peripheral portion of the upper surface of the wafer from at least three of the edge nozzles disposed at peripheral locations along a circle whose center coincides with the central location, and at flow rates greater at each of these peripheral locations than the flow rate at which the gas is injected from said central location.

According to another aspect of the present invention, semiconductor manufacturing equipment is provided with a controllable distributor operatively interposed between a supply line and the nozzles so as to control the flow of the process gas from the supply line to the nozzles. A controller is operatively connected to the distributor for controlling the distributor to regulate the flow of the process gas to the nozzles.

According to another aspect of the present invention, a method of processing the wafer includes controlling the flow rate of the process gas injected onto the upper surface of the wafer from central and peripheral locations on the basis of at least the process atmosphere formed in the chamber. First, information regarding the processing of the wafer is collected. Process conditions to be created in the processing chamber are determined based on the information. Then, the process atmosphere is formed in the chamber on the basis of the determined process conditions. Process gas supplied to the chamber is injected onto a central portion of an upper surface of the wafer from a central location directly above the center of the wafer, and from locations disposed above the periphery of the wafer. The flow rates of the process gas are controlled to achieve the desired distribution across the wafer surface.

### BRIEF DESCRIPTION OF THE DRAWINGS

The present invention will become more fully understood from the following detailed description made with reference to the accompanying drawings in which:

FIG. 1 is a sectional view of prior art semiconductor device manufacturing equipment using radio frequency power;

FIG. 2 is a bottom view of an upper electrode of the semiconductor device manufacturing equipment shown in FIG. 1;

FIG. 3 is a perspective view of a nozzle of the upper electrode shown in FIG. 2;

FIG. 4 is a schematic diagram of the distribution of the process gas supplied by the upper electrode onto the upper surface of a wafer;

FIG. 5 is a diagram showing the Gaussian distribution of the density of the process gas on the wafer according to the distribution of the process gas illustrated in FIG. 4;

FIG. 6 is a simulation of the results of a process performed on a wafer when the process gas has a density distribution as shown in FIG. 5;

FIG. 7a is a photograph of a wafer showing the defect of a process performed when the density of process gas has the distribution shown in FIG. 5

FIG. 7b is a photograph of a portion of the bottom surface of the upper electrode showing hemi-spherical defects on the electrode as a result of the process performed when the process gas has the distribution shown in FIG. 4;

FIG. 7c is a photograph of a portion of the wafer surface showing a defect created as the result of the defects formed on the upper electrode as shown in FIG. 7b;

FIG. 8 is a graph of data showing the frequency of material defects per changes in the level of radio frequency power applied to process gas distributed as shown in FIG. 5;

FIG. 9 is a graph of data showing the frequency of material defects per changes in the level of vacuum pressure within the processing chamber when process gas introduced into the chamber is distributed as shown in FIG. 5;

FIG. 10 is a graph of data showing the frequency of material defects per changes in the flow rates for constituents of a process gas distributed as shown in FIG. 5;

FIG. 11a is a bottom view of a first embodiment of an upper electrode according to the present invention;

FIG. 11b is a bottom view of a second embodiment of an upper electrode according to the present invention;

FIGS. 12a and 12b are perspective views of the nozzles of the upper electrode shown in FIG. 11b;

FIG. 13 is a schematic diagram of the distribution of the process gas supplied by the upper electrode of FIG. 11b onto the upper surface of a wafer;

FIG. 14 5 is a diagram showing the Gaussian distribution of the density of the process gas on the wafer according to the distribution of the process gas illustrated in FIG. 13;

FIG. 15 shows a simulation of the results of a process performed using the upper electrode of FIG. 11b but wherein the process gas through the central nozzle was cut off;

FIG. 16 shows a simulation of the results of a process performed using the upper electrode of FIG. 11b and wherein the process gas through the central nozzle has a flow rate of 7˜10 weight % per unit time;

FIG. 17 is a graph of the frequency of material-based defects resulting from processes carried out at various levels of a radio frequency power using the upper electrode according to the present invention;

FIG. 18 is a graph of the frequency of material-based defects resulting from processes carried out at various levels of a vacuum pressure using the upper electrode according to the present invention;

FIG. 19 is a graph of the frequency of material-based defects resulting for various process gases injected using the upper electrode according to the present invention;

FIG. 20 is a sectional view of semiconductor manufacturing equipment according to the present invention and provided with the upper electrode of FIG. 11a or 1b;

FIG. 21 is a partial sectional view of another embodiment of a distributor for the semiconductor manufacturing equipment of FIG. 20;

FIG. 22 is a perspective view, partially in section, of part of another embodiment of a distributor for the semiconductor manufacturing equipment of FIG. 20;

FIG. 23 is a flowchart of a method of supplying process gas according to the present invention; and

FIG. 24 is a block diagram of the database of the semiconductor manufacturing equipment of FIG. 20.

### DETAILED DESCRIPTION OF THE PREFERRED EMBODIMENTS

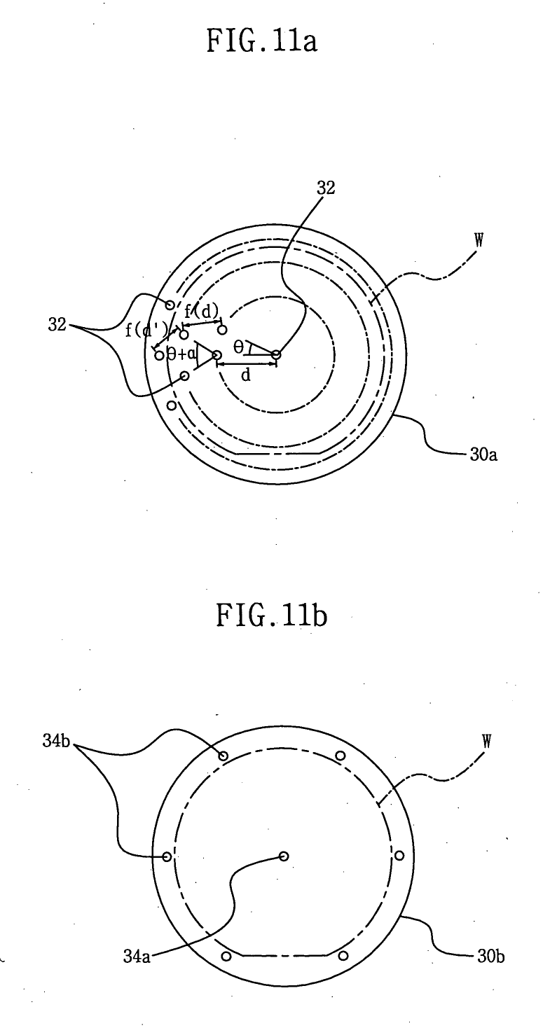

The preferred embodiments of the present invention will now be described in detail with reference to FIGS. 11 through 24.

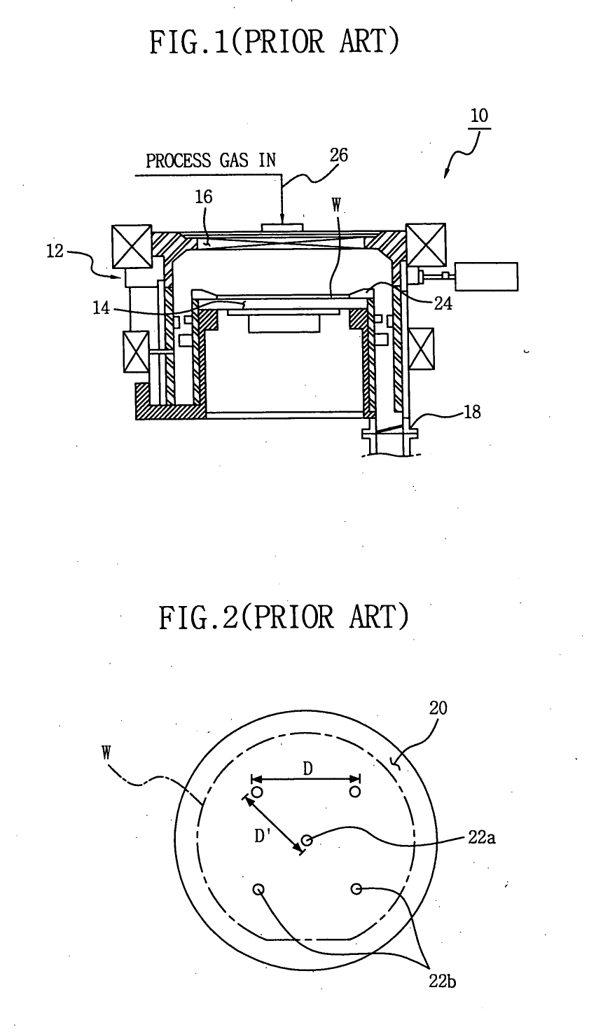

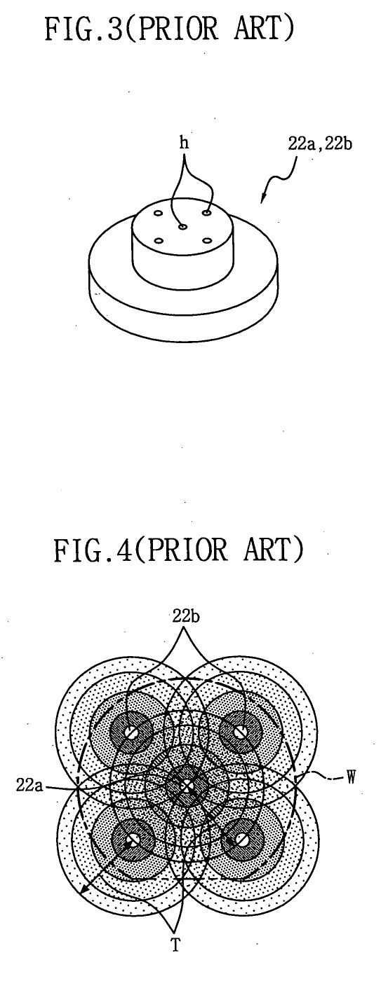

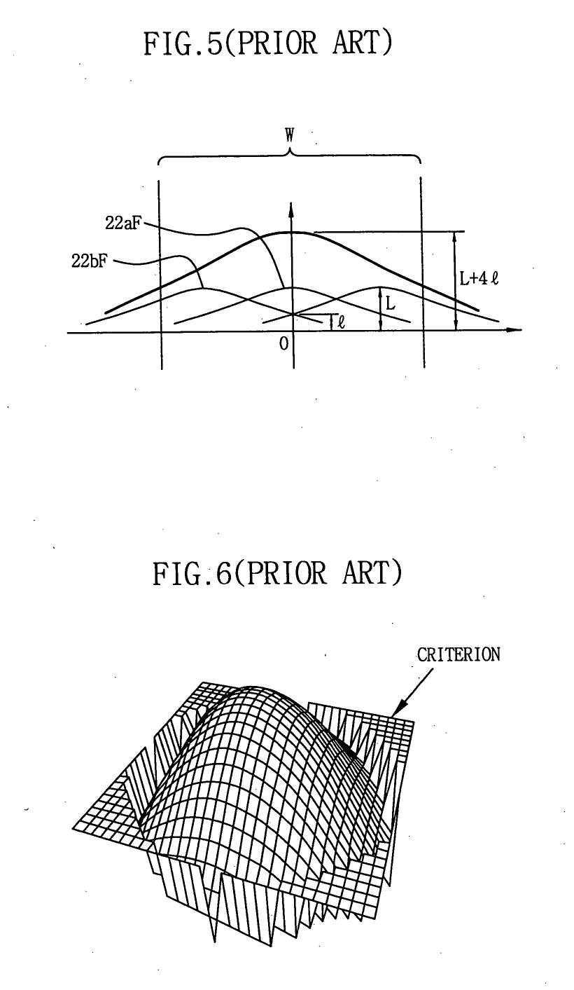

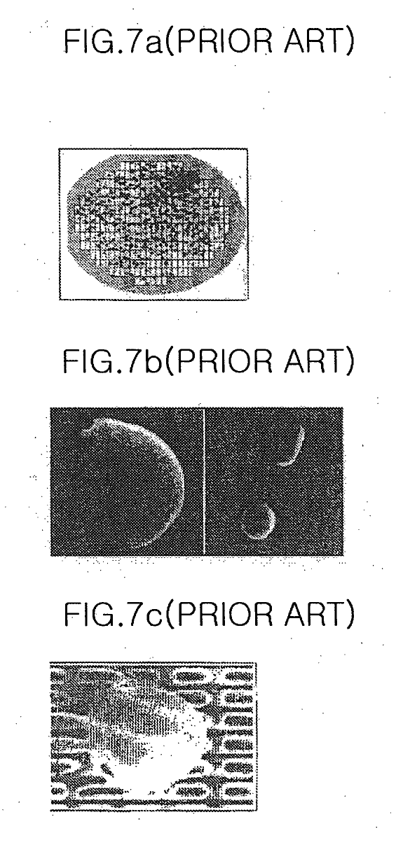

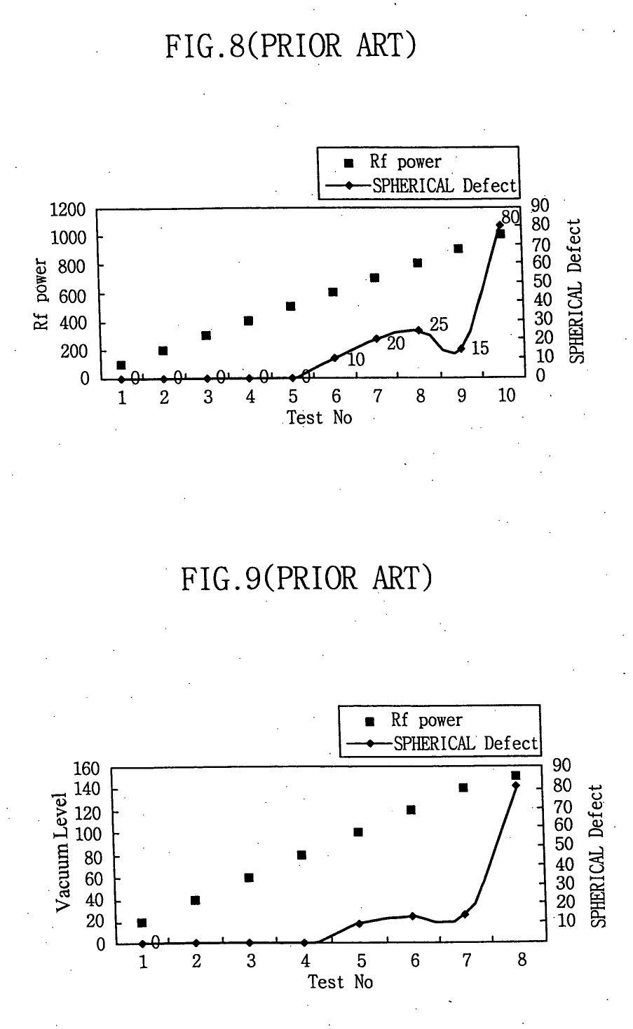

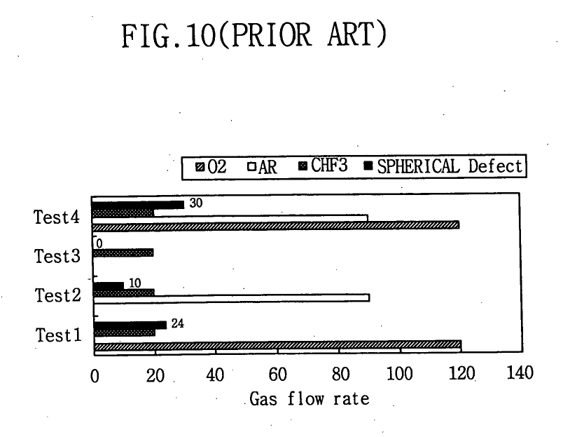

The semiconductor device manufacturing equipment may have the same general structure as that shown in FIG. 1 and therefore, a detailed description thereof will be omitted.

According to a first embodiment of the present invention as shown in FIG. 11a, the upper electrode 16 includes an electrode plate 30a, and a plurality of nozzles 32 of the same shape integral with the electrode plate 30a. The nozzles 32 thus inject the process gas at the same rate. Moreover, one nozzle 32 is disposed at the center of the electrode plate 32a, and the remainder of the nozzles 32 are disposed in a plurality of concentric groups about the central nozzle 32. The nozzles 32 in each group are spaced apart from one another by equal amounts. Also, the nozzles 32 are disposed more densely at an outer peripheral portion of the electrode plate 30a than at a central portion of the electrode plate 30a. The intervals (d, f(d), f(d′), . . . ) between the central nozzle 32 or nozzles 32 in any one group, and closest nozzles 32 in the adjacent group decrease in the radial direction, i.e., in a direction from the center of the electrode plate 30a toward the outer peripheral edge portion thereof. Still further, the nozzles 32 are arranged so that the angle subtended between a nozzle 32 in one group, and the closest two nozzles in the adjacent group increases in the radial direction (depicted as θ<θ+a in the figure).

Thus, the flow rate of the gas provided by the nozzles 32 increases in a direction from the center of the wafer W towards the outer peripheral edge portion of the wafer. The flow rate of the process gas at the central portion of the wafer W is, in fact, relatively low compared to the levels that exist radially outwardly thereof. As a result, the process gas supplied through the respective nozzles 32 can have a substantially uniform density distribution across the entire upper surface of the wafer.

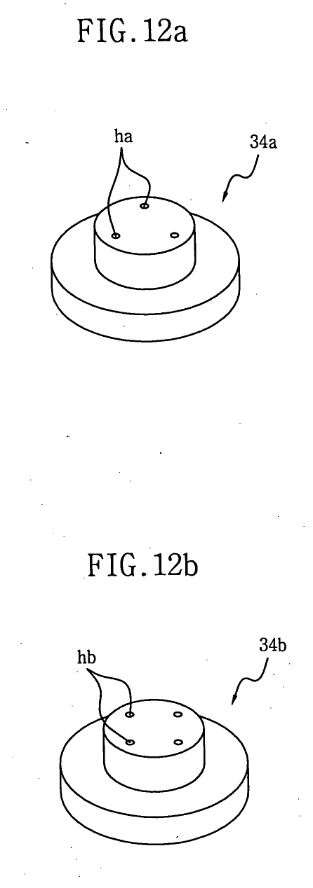

In the embodiment of FIGS. 11b, 12a and 12b, a central nozzle 34a is disposed at the center of the electrode plate 30b, and at least one concentric group of edge nozzles 34b is centered about the central nozzle 34a. Each group of nozzles 34b is made up of at least three nozzles, and the nozzles 34 are spaced apart by equal intervals within each group. Still further, the numbers of edge nozzles 34b of each group increases from group to group in the radial direction of the electrode plate 30b.

The flow rate of process gas issuing from the central nozzle 34a is 0˜15 weight % of the entire amount of the process gas supplied into the chamber by the edge nozzles 34b. The plurality of edge nozzles 34b supply the process gas at equal flow rates. Further, the flow rate of the process gas supplied by each of the edge nozzles 34b is higher than the flow rate of the process gas supplied by the central nozzle 34a.

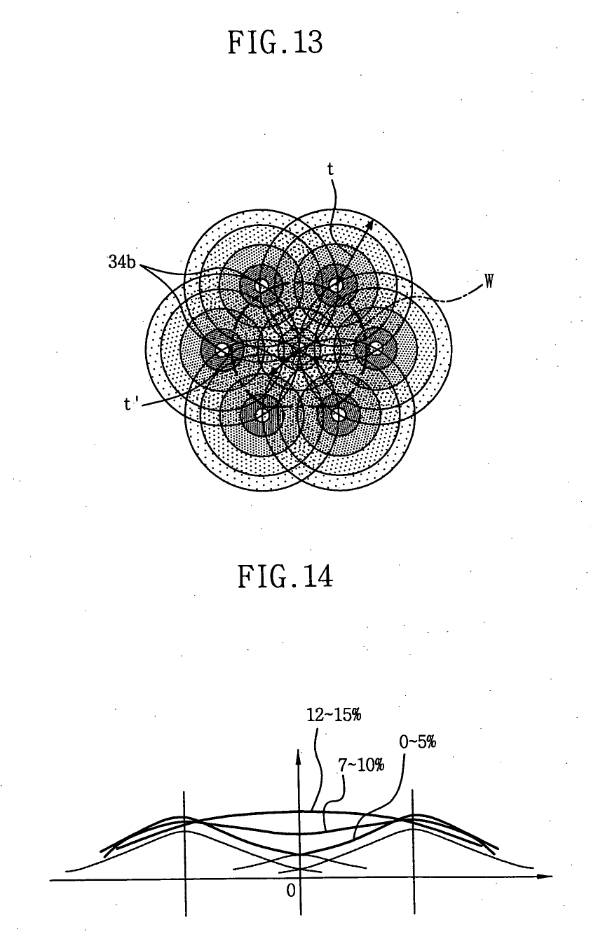

Thus, the gas is distributed as shown in FIG. 13. That is, the range (t′) over which the process gas supplied through the central nozzle 34a spreads over the upper surface of the wafer W is limited to a central portion of the upper surface. On the other hand, the range (t) over which the process gas supplied by each edge nozzle 34b is relatively wide. Accordingly, the density distribution of the process gas across the entire upper surface of the wafer W is substantially uniform, due to the overlapping of the relatively broad regions (t) with the central region (t′).

As shown in FIGS. 12a and 12b, the nozzles 34a,34b have respective sets of gas holes ha, hb. The size (sectional area) of the gas holes of each nozzle 34a or 34b may be the same. However, the size (area) of the gas holes (hb) of each edge nozzle 34b is larger than the size of the gas holes (ha) of the central nozzle 34a. In other words, the size of the gas holes maybe such that the flow rate of the process gas through each of the edge nozzles 34b is higher than that through the central nozzle 34a. In addition, each of the edge nozzles 34b can have a greater number of gas holes than the central nozzle 34a.

In the embodiments described above, the process gas flowing through the supply line 26 from the upper side of the electrode plate 30a or 30b induced into the chamber 12 by supply pressure provided in the line 26 and/or by the vacuum pressure prevailing in the chamber 12. The process gas thus flows through the respective nozzles 32 or 34a, 34b integrated with the electrode plate 30a or 30b. At this time, the overall flow rate of the process gas at a peripheral portion of the wafer is greater than that at a central portion of the wafer W. The overlapping regions of the process gas supplied in this state thus are uniformly distributed, in terms of its density, across the entire upper surface of the wafer W, as shown in FIG. 14.

As a result, when the process gas is excited by radio frequency power, the process reaction is uniform across the entire upper surface of the wafer W. Thus, process defects are prevented or substantially mitigated. Furthermore, even if the radio frequency power is concentrated at the central portion of the upper electrode, only a very small a potential difference occurs between the gas located at the central region and the gas at the peripheral edge region. Accordingly, the likelihood of an electrical discharge occurring is minimal and thus, material defects are prevented.

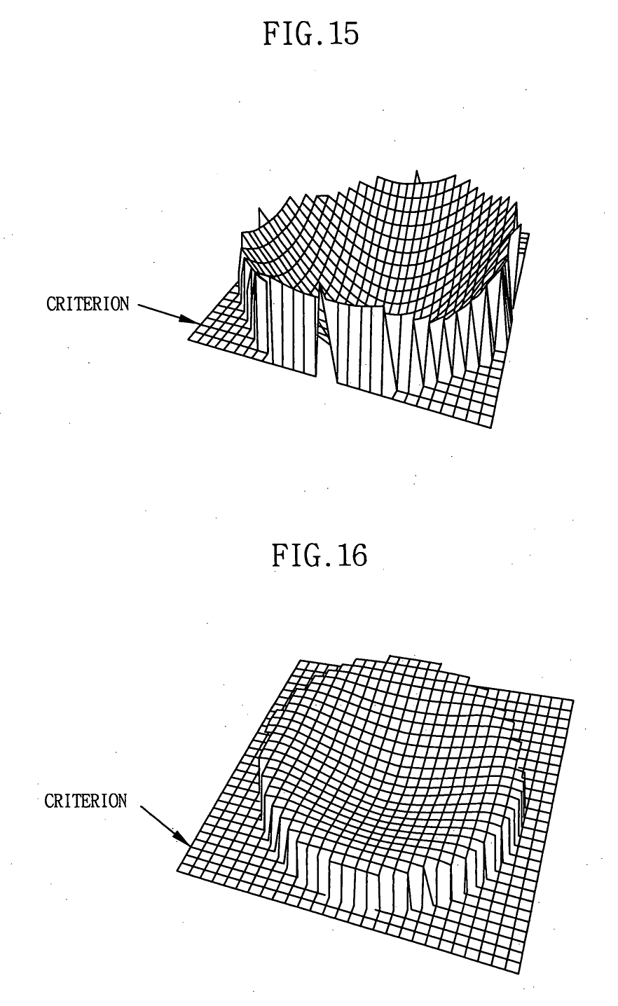

FIG. 15 shows the average result of simulations of numerous processes performed on the wafer W using the embodiment of FIG. 11b but wherein the central nozzle 34a is completely cut off. In this case, the result shows even a greater processing uniformity compared to the prior art (refer back to FIG. 6).

FIG. 16 shows the average result of simulations of numerous processes performed on the wafer W using the embodiment of FIG. 11b. In these simulations, 7˜10 weight % of the total amount of the process gas was supplied through the central nozzle 34a vertically opposite the center of the wafer W. FIG. 16 shows a remarkably enhanced process uniformity and stabile process reaction, not only in comparison with the prior art but also in comparison with the simulations that produced the graph of FIG. 15.

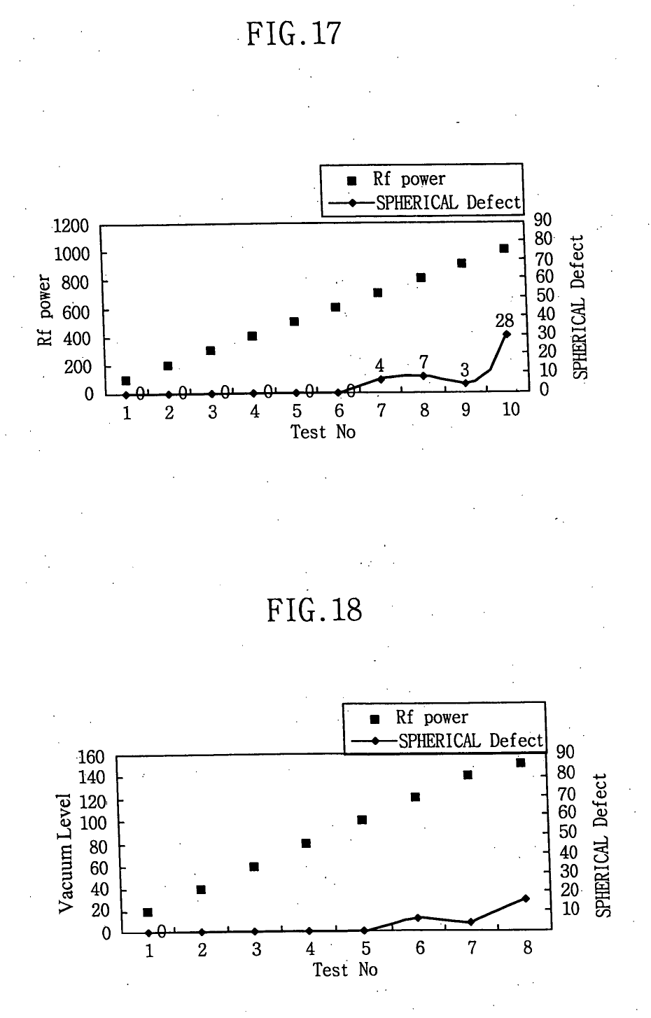

FIG. 17 shows data of the frequency of material-based defects as the level of radio frequency power is gradually increased and the present invention is employed.

FIG. 18 shows data of the frequency of material-based defects when the level of vacuum pressure in the chamber is gradually increased and the present invention is employed. As is clear form this data, the frequency of the material-based defects caused by an electrical discharge in the chamber is substantially less than in the prior art. This indicates that the levels of the radio frequency power and vacuum pressure can be higher than in the prior art before the frequency of defects becomes unacceptable.

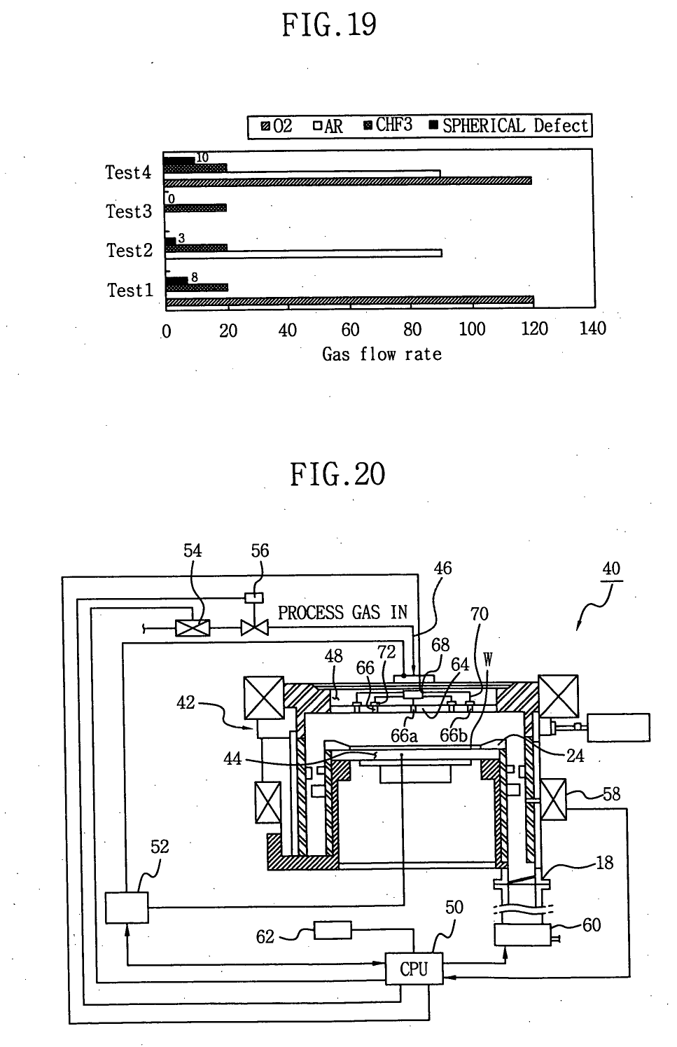

FIG. 19 shows the frequency of material-based defects for the flow rate of the process gases taken from the test results described in connection with FIGS. 17 and 18. FIG. 19 shows that the present invention allows for a broader range in the levels of the radio frequency power and the vacuum pressure that can be used to carry out the process.

Next, another embodiment of semiconductor device manufacturing equipment according to the present invention will be described with reference to FIG. 20. The equipment 40 comprises a sealed process chamber 42, a lower electrode 44 disposed on a lower portion of the process chamber 42, and an upper electrode 48 disposed in an upper part of the chamber 42. The lower electrode 44 supports a wafer W in the chamber 42. The upper electrode 48 directs a process gas from a supply line 46, connected to an upper side of the electrode 48, onto the upper surface of the wafer W. The upper and lower electrodes 44, 48 are each connected a radio frequency oscillator 42 controlled by a controller 50.

Furthermore, the supply line 46 is equipped with a flow meter 54 for measuring the amount of process gas flowing through the supply line 46, and a control valve 56 for controlling the flow of the process gas in response to a control signal issued by the controller 50. The control signal is generated on the basis of a signal from the flow meter 54 indicative of the measurements made by the flow meter 54.

A pressure sensor 58 is provided on one side portion of the chamber 42 for measuring the pressure in the chamber. A vacuum pump 60 is connected to the chamber 42 through an exhaust line 18. The vacuum pump 60 is controlled in response to a control signal issued thereto by the controller 50. Furthermore, the controller 50 is connected to a database 62 of information containing various kinds of process conditions for the wafer W.

The upper electrode part 48, as is also shown in FIG. 20, comprises an electrode plate 64, a central nozzle 66a disposed at the center of the electrode plate 64 so that a portion the process gas flows therefrom towards a central portion of the wafer W vertically opposite the central nozzle, and one or more concentric groups of edge nozzles 66b centered about nozzle 66a. At least three of such edge nozzles 66b constitute each group, and are spaced from one another within each group by equal intervals. The edge nozzles 66b uniformly divide the remainder of the process gas and direct the gas as respective gas flows towards the wafer W.

A distributor is provided on an upper part of the electrode plate 64. The distributor is adapted to control and distribute the amount of process gas flowing from the supply line 46 to each location where the central nozzle 66a and a group of the edge nozzles 66b are disposed, in response to a control signal issued by the controller 50.

In one example, the distributor 68 includes pipes 70 that diverge from the supply line 46 to the central nozzle 66a and to each group of the edge nozzles 66b, and a control valve (not shown) provided in-line with each divergent pipe 70 to control the flow rate of the process gas through the divergent pipes 70 in response to a control signal issued by the controller 50. The divergent pipes 70 may be connected to buffers that serve to provide uniformity in the pressure of the process gas supplied through the divergent pipes 70 to each group of edge nozzles 66b.

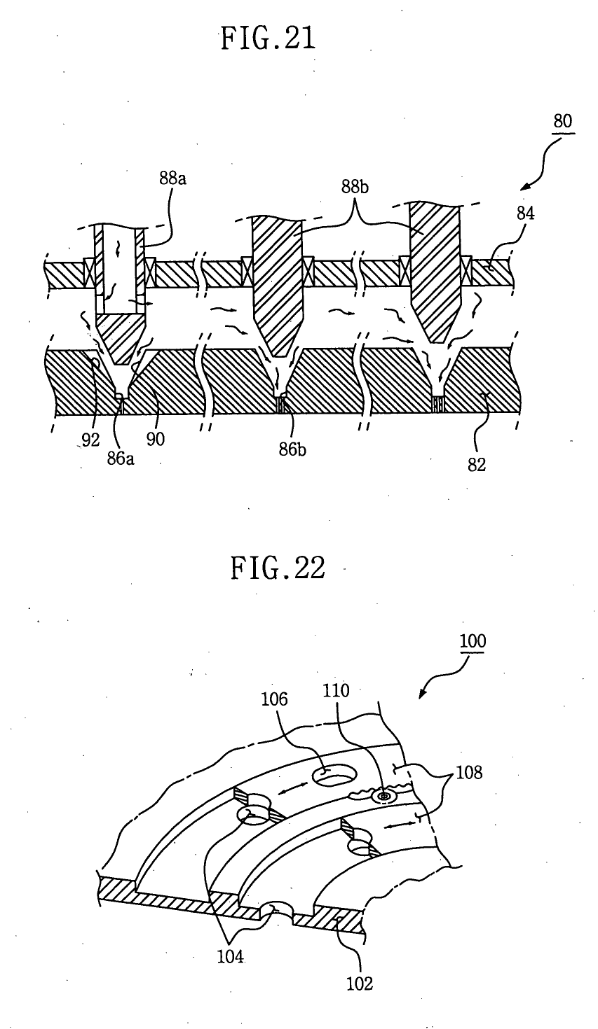

In another example of the distributor, as shown in FIG. 21, the distributor 80 comprises a support plate 84 spaced above the electrode plate 82. Adjustable control members 88a, 88b are mounted on the support plate 84 so as to be movable up and down relative to the plate 84. The control members 88a, 88b are disposed opposite the central nozzle 86a and the respective edge nozzles 86b, respectively. An elevating mechanism (not shown) controls the vertical position of control members 88a, 88b in response to a control signal issued by the controller 50. Accordingly, the amount of process gas supplied through each of the nozzles 86a, 86b can be controlled by the positioning of the control members 88a, 88b.

Also, the electrode plate 82 may have grooves 90 disposed opposite the control members 88a, 88b. The shape of the lower end of the control members 88a, 88b can match that of the grooves 90 so that the control members 88a, 88b can be seated against the electrode plate 82 within each of the grooves. The electrode plate may also have flutes 92 that define each groove 90 so that the nozzles are not entirely blocked when the control members 88a, 88b are seated against the electrode plate 82 within each of the grooves. The flutes 92 thus establish the minimal flow rate of the process gas flowing through each nozzle 86a, 86b.

In still another example of the distributor, as shown in FIG. 22, the distributor 100 includes an adjustable control plate 108 for controlling the degree of opening of a plurality of nozzles 104 of an electrode plate 102. The control plate 108 has through-holes 106 each corresponding to one of the nozzles 104. The control plate 108 can be rotated by a rotary angle controller 110 that is supported by the electrode plate 102.

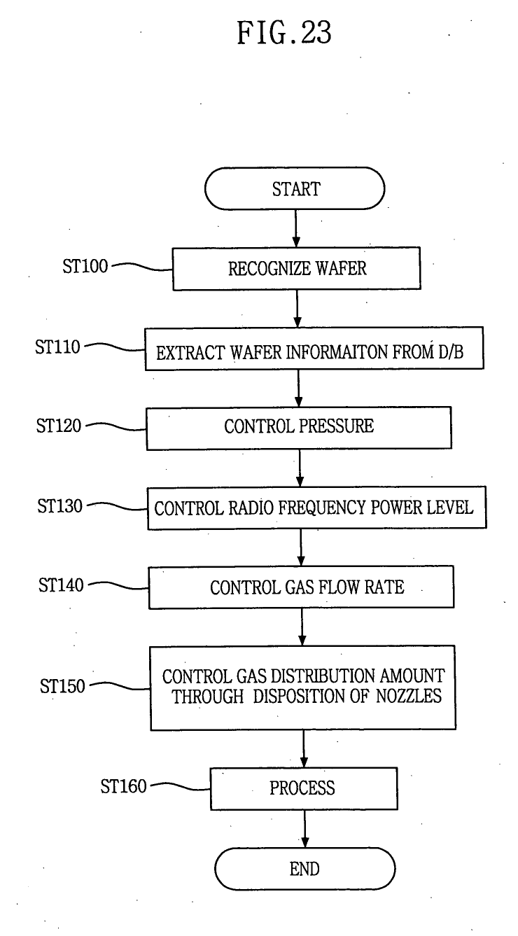

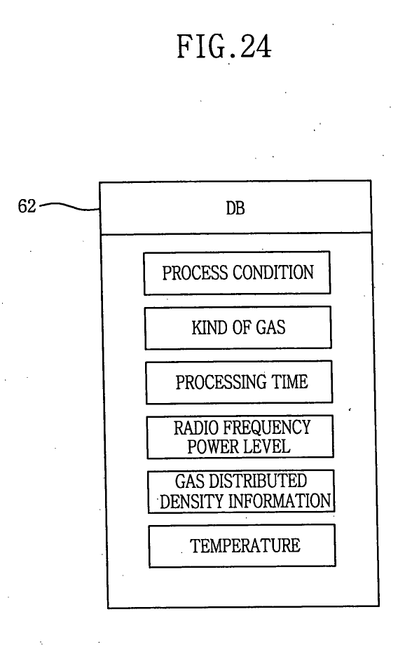

FIG. 23 illustrates a method according to the present invention. FIG. 24 illustrates an example of the configuration of the database 62. First, the wafer W is supplied into the chamber 42 and is stably mounted on the lower electrode 44. Then the controller 50 recognizes a previous state or a stably mounted state of the wafer W (ST100). Various information regarding the processing of the wafer W is received from the database 62, and the process conditions to be created in the chamber are determined based on that information (ST110). These process conditions include the level of radio frequency power, the level of vacuum pressure and the processing time together with a kind(s) of process gases necessary for the process.

Next, the controller 50 monitors the vacuum pressure atmosphere in the chamber using the pressure sensor 58, and controls the vacuum pump 60 to form a desired level of vacuum pressure in the chamber 42 (ST120). Once the desired level of vacuum pressure is formed, the controller 50 controls the radio frequency oscillator 52 to produce a desired level of radio frequency power (ST130). Then, the distributor is controlled to adjust the flow rates of the process gas (ST140) supplied to the nozzles such that the density of the process gas is uniform from the central portion to the edge portion of the wafer W (ST150). Subsequently, the wafer W is processed (ST160) once the process gas is distributed uniformly across the entire upper surface of the wafer W.

As described above, a plurality of nozzles are configured so that the flow rate of process gas is greater overall across from a peripheral portion of a wafer than across from a central portion thereof. Thus, the distribution of the density of the process gas is uniform across the entire upper surface of the wafer thereby ensuring processing uniformity and the prevention of processing defects. Also, no additional or dedicated process is required to remove material in the case of an etch process.

The processing reaction is also enhanced thereby minimizing the processing time and increasing productivity. Also, the process conditions can be changed rapidly and stably, even throughout the course of supplying process gases of various kinds during a specific process.

It will be apparent to those skilled in the art that the present invention can be changed or modified without deviating from the true spirit of the invention. Accordingly, such changes and modifications are seen to be within the true scope of the invention as defined by the appended claims.

What is claimed is:

1. An upper electrode for supplying process gas onto a wafer in semiconductor device manufacturing equipment, comprising:
a plate electrode, and a plurality of nozzles integral with said plate electrode so as to inject process gas supplied at one side of the plate electrode into a processing chamber from the other side of the plate electrode, said nozzles being configured to inject the process gas at a flow rate that is higher overall at a peripheral portion of said plate electrode than at a central portion of said plate electrode located radially inwardly of the peripheral portion.

2. The electrode as claimed in 1, wherein said plurality of nozzles are identical with respect to their configurations such that said nozzles will inject the process gas at equal flow rates, and the nozzles are disposed more densely at the outer peripheral portion of the plate electrode than at the central portion of the plate electrode.

3. The electrode as claimed in 1, wherein said plurality of nozzles include nozzles at the outer peripheral portion of the plate electrode, and a nozzle at the central portion of the plate electrode, and the nozzles at the outer peripheral portion of the plate electrode have configurations that are different from the nozzle at the central portion of the plate electrode, each of said nozzles at the outer peripheral portion of the plate electrode being configured to inject the process gas at a higher flow rate than the nozzle at the central portion of the plate electrode.

4. The electrode as claimed in 3, wherein said nozzles at the peripheral portion of the electrode plate are arrayed in at least one concentric group centered about the nozzle at the central portion of the plate electrode, and the nozzles within each said group have the same configurations so as to inject the process gas at the same flow rate.

5. The electrode as claimed in 3, wherein said nozzles at the peripheral portion of the electrode plate have through-holes that are larger than those of the nozzle at the central portion of the plate electrode.

6. The apparatus as claimed in 3, wherein each of said nozzles at the peripheral portion of the electrode plate has a number of through-holes greater than the number of the through holes of the nozzle at the central portion of the plate electrode.

7. A method of supplying process gas onto the surface of a wafer in semiconductor device manufacturing equipment having a processing chamber in which the wafer is supported, and a radio frequency power source for exciting the process gas, said method comprising:
supplying process gas to the chamber;
injecting the supplied process gas at a flow rate of 0˜15 weight percent per unit time, of the total amount of the process gas being supplied, onto a central portion of an upper surface of the wafer from a central location directly above the center of the wafer; and
injecting the remainder of the supplied process gas onto a peripheral portion of the upper surface of the wafer from at least three peripheral locations disposed above the wafer and at equal intervals from each other along a circle whose center coincides with said central location, and at flow rates greater at each of said peripheral locations than the flow rate at which the gas is injected from said central location.

8. The method as claimed in 7, wherein said peripheral locations are located vertically opposite the outer peripheral edge of the wafer.

9. Semiconductor manufacturing equipment, comprising:
a processing chamber;
a supply line through which process gas is supplied to said chamber;
a central nozzle disposed at an upper part of said chamber;
a plurality of edge nozzles disposed at the upper part of said chamber at peripheral locations, respectively, disposed at equal intervals from each other along a circle whose center coincides with said central nozzle;
a controllable distributor operatively interposed between said supply line and said nozzles so as to control the flow of the process gas from the supply line to the nozzles;
an exhaust system connected to said processing chamber to create a vacuum within the chamber;
a pressure sensor that measures the pressure in the chamber interior;
a database that stores information regarding the processing of a wafer within said chamber; and
a controller operatively connected to said database so as to receive the information stored by the database, operatively connected to said pressure sensor and said exhaust system so as to control the exhaust system to regulate the pressure with the chamber on the basis of the pressure sensed by said sensor, and operatively connected to said distributor for controlling the distributor to regulate the flow of the process gas to said nozzles.

10. The equipment as claimed in 9, wherein the distributor comprises:
pipes diverging from the supply line and each connected to a respective one of the central nozzle and the edge nozzles; and
a control valve disposed in-line with the divergent pipes, and operatively connected to said controller.

11. The equipment as claimed in 9, wherein the distributor comprises:
a support plate disposed above said nozzles;
and control members supported by said support plate so as to be movable in a direction towards and away from said nozzles; and
an elevating mechanism operatively connected to said control members so as to position said control members relative to said valves, said elevating mechanism being operatively connected to said controller.

12. The equipment as claimed in 11, and further comprising a plate electrode with which said nozzles are integrated, said having a plurality of grooves extending from an upper surface thereof to each of said nozzles, respectively, and wherein each of said control members has a lower end having a shape corresponding to the shape of a respective one of said grooves and is disposed opposite thereto, whereby the control members can be seated in said grooves.

13. The equipment as claimed in 9, and further comprising a plate electrode with which said nozzles are integrated,
and wherein the distributor comprises:
an adjustable control plate disposed on said plate electrode so as to be rotatable in a circumferential direction of said plate electrode, and having through-holes each corresponding to a respective one of said nozzles; and
a rotary drive mechanism supported by the electrode plate and operatively connected to said control plate so as to position the control plate in the circumferential direction relative to said plate electrode.

14. A method of processing a wafer using process gas, comprising,
disposing the wafer in a processing chamber;
collecting the information regarding the processing of the wafer;
determining process conditions to be created in the processing chamber based on the information;
forming a process atmosphere in the chamber on the basis of the determined process conditions;
supplying process gas to the chamber;
applying a radio frequency power to the chamber to excite the process gas;
injecting the supplied process gas onto a central portion of an upper surface of the wafer from a central location directly above the center of the wafer, and
simultaneously injecting the remainder of the supplied process gas onto a peripheral portion of the upper surface of the wafer from peripheral locations disposed above the wafer and at equal intervals from each other along a circle whose center coincides with said central location; and
controlling the flow rate of the process gas injected onto the upper surface of the wafer from said central and peripheral locations on the basis of the process atmosphere formed in the chamber.

15. The method as claimed in 14, wherein the flow rate of the process gas is controlled also on the basis of the level of radio frequency power applied.
